(19) United States
(12) Patent Application Publication
(10) Pub. No.: US 2017/0018541 A1
(43) Pub. Date: Jan. 19, 2017

(54) WIRING BOARD AND MEMORY SYSTEM INCLUDING THE SAME

(71) Applicant: SAMSUNG ELECTRONICS CO., LTD., Suwon-si (KR)

(72) Inventors: DOO-JIN YI, SEOUL (KR); IN-BO SHIM, OSAN-SI (KR); JAE-SANG YUN, SUWON-SI (KR); YOUNG-JOON JANG, SEOUL (KR)

(21) Appl. No.: 15/207,520

(22) Filed: Jul. 12, 2016

(30) Foreign Application Priority Data
Jul. 17, 2015 (KR) 10-2015-0101990

(51) Int. Cl. H01L 25/18; H01L 23/367; H01L 23/498

(52) U.S. Cl. CPC H01L 25/18; H01L 23/49805; H01L 23/49838; H01L 23/49822; H01L 23/3675; H01L 23/49827

(57) ABSTRACT

A memory system includes a package having a memory device, and a wiring board to which the package is attached. The wiring board includes a first region and a second region separable from the first region. The first region may conform in terms of its dimensions and other physical characteristics to a first form factor of the memory system, and the first and second regions collectively may conform in the same way to a second form factor of the memory system.

### PRIORITY STATEMENT

This application claims the benefit of Korean Patent Application No. 10-2015-0101990, filed on Jul. 17, 2015, in the Korean Intellectual Property Office, the disclosure of which is hereby incorporated by reference in its entirety.

### BACKGROUND

The inventive concept relates to electronic systems including memory devices such as solid state drives (SSDs). More particularly, the inventive concept relates to a wiring board and to a memory system including the same.

Memory devices are used to store data, and can be classified as volatile or non-volatile memory devices. An example of a non-volatile memory device is a flash memory. Flash memories can be used for mobile phones, digital cameras, personal digital assistants (PDAs), portable computer devices, fixed computer devices, and the like.

A memory device, such as a flash memory, may be mounted to a wiring board along with the other electronic components such as a memory controller that controls various operations of the memory device so as to constitute what may be referred to herein as a memory system. The wiring board includes a substrate and one or more levels of wiring patterns integral with the substrate and electrically connected to the components. Thus, respective ones of the components may be operatively connected to one another, e.g., so as to electrically connect a memory device and a memory controller. In the case of multiple levels of wiring patterns, the wiring board will typically have electrically conductive vias extending vertically between and electrically connecting the levels of wiring patterns. The wiring board will also typically have some form of external contacts by which the components can be connected to an external device, namely, a host device.

Typically, a memory system has physical dimensions and other structural characteristics, e.g., the location and configuration of external contacts, which are standardized. The form factor of a memory system may refer to an industry standard for the set of physical dimensions of the electronic components of the system or may refer to the set of standardized physical characteristics of the system itself. With respect to the latter, host devices are designed to accept a memory system of one particular form factor.

### SUMMARY

According to an aspect of the inventive concept, there is provided a memory system including: a package comprising a memory device of the memory system, and a wiring board to which the package is mounted and comprising a substrate and at least one layer of a conductive pattern integral with the substrate, and in which the memory system has a first region, a second region, and at least one boundary region including a first boundary region between the first region and the second region, the wiring board is frangible at or physically divided along the first boundary region, the at least one layer comprises a conductive pattern extending along an outer surface of the substrate in the first region, and the package is confined to the first region as attached to the conductive pattern, and the first region conforms to a first form factor of the memory system, and a third region consisting of the first and second regions together conform to a second form factor of the memory system.

According to another aspect of the inventive concept, there is provided a wiring board including: a substrate and at least one layer of a conductive pattern integral with the substrate, and in which the wiring board has a first region and a second region, the at least one layer includes a conductive pattern extending along one of oppositely facing major surfaces of the substrate and at which a memory device can be attached and electrically connected to the wiring board, the wiring board is frangible at or physically divided along the first boundary region, and the first region conforms to a first form factor of a memory system that employs the memory device, and the first and second regions together conform to a second form factor of the memory system.

According to still another aspect of the inventive concept, there is provided a memory system including:

a wiring board comprising a substrate and wiring integral with the substrate, and electronic components of the memory system mounted to the wiring board at the first surface of the substrate and electrically connected to the wiring, and in which the memory system has a plurality of body regions integral with one another, a respective boundary region between adjacent ones of each respective pair of the body regions, and means for detaching the adjacent ones of the body regions from one another along the respective boundary region located therebetween, the electronic components comprise at least one electronic memory and a memory controller operatively electrically connected to the at least one memory, the first one of the body regions is adjacent to only one other of the body regions such that the first one of the body regions including each said at least one electronic memory and the memory controller can be detached from all other of the body regions along a said boundary region between the first one of the body regions and said one other of the body regions, and the memory system is operable in at least a first configuration in which the first one and said other of the body regions remain integral with each other, and a second configuration in which the first body region has been detached by virtue of said detaching means from said other of the body regions along the boundary region located therebetween.

Thus, the memory system is adaptable for use with any of a plurality of different hosts configured to receive memory systems of different physical dimensions or having different form factors dictating at least key physical dimensions of the bodies of the memory systems.

### BRIEF DESCRIPTION OF THE DRAWINGS

Examples of the inventive concept will be more clearly understood from the following detailed description taken in conjunction with the accompanying drawings in which:

FIG. 1 is a block diagram of components making up various examples of a memory system according to the inventive concept;

FIG. 2 is a diagram of perspective views of memory systems showing an evolution of memory systems in the art;

FIG. 3A is a diagram of plan views of several examples of the memory systems configured identically to one another, and as shown in FIG. 1, but having different form factors;

FIG. 3B is a diagram of plan views of two other examples of the memory systems configured identically to one another, and as shown in FIG. 1, but having different form factors;

FIGS. 4A and 4B are plan views of examples of memory systems according to the inventive concept, respectively;

FIGS. 5A and 5B are sectional views of examples of wiring boards, according to the inventive concept, as respectively taken in a direction corresponding to the direction of line X-X′ of FIG. 4A;

FIG. 5C is a perspective view of part of another example of a wiring board according to the inventive concept;

FIG. 6 is a plan view of another example of a memory system according to the inventive concept;

FIG. 7 is a plan view of still another example of a memory system according to the inventive concept;

FIG. 8 depicts representational diagrams of memory systems according to the inventive concept along with a host device;

FIG. 9 is a block diagram of a memory system, which includes optical links, according to the inventive concept.

FIG. 10 shows is a schematic diagram, in perspective, of a package including a memory device and a memory controller that may be employed in a memory system according to the inventive concept; and

FIG. 11 is a block diagram of a computing system including an example of a memory system according to the inventive concept.

### DETAILED DESCRIPTION

Hereinafter, examples of the inventive concept will be described in detail with reference to the accompanying drawings. It should be understood that the examples of the inventive concept are provided for thorough understanding of the inventive concept by those of ordinary skill in the art. Since the inventive concept may be embodied in different ways, specific examples will be illustrated in the drawings and described in detail. However, it should be understood that the specific examples are not to be construed in any way as limiting the inventive concept, and that various modifications, changes, alterations, and equivalent examples can be made by those of ordinary skill in the art without departing from the spirit and scope of the inventive concept. Like components will be denoted by like reference numerals throughout the specification. In the drawings, the sizes of components may be exaggerated for clarity.

As used herein, the term “and/or” includes any and all combinations of one or more of the associated listed items. Expressions such as “at least one of” when preceding a list of elements, modify the entire list of elements and do not modify the individual elements of the list.

The terminology used herein is only for the purpose of describing specific examples and is not intended to limit the inventive concept. As used herein, the singular terms “a,” “an” and “the” are intended to include the plural forms as well, unless the context clearly indicates otherwise. It will be understood that the terms such as “comprises”, “comprising”, “includes”, “including”, “has”, and “having”, when used herein, specify the presence of stated features, numbers, steps, operations, components, parts, or combinations thereof, but do not preclude the presence or addition of one or more other features, numbers, steps, operations, components, parts, or combinations thereof.

It will be also understood that although the terms such as “first”, “second” and the like may be used herein to describe various components, these components should not be limited by these terms. These terms may be used to distinguish one component from another component. For example, a first component could be termed a second component, and similarly, a second component could also be termed a first component, without departing from the spirit and scope of the inventive concept.

Unless otherwise defined, all terms used herein, including technical and scientific terms, have the same meanings as generally understood by those of ordinary skill in the art. For example, the term “form factor” may be understood as referring to a standardized set of physical characteristics, i.e., overall physical dimensions and the like, of a system of components. The term “pattern” may refer to any patterned layer of material regardless of whether that pattern remains as a contiguous layer of the material or includes discrete segments of the material spaced from one another. The term “region” as used herein is generally synonymous with “section” or “portion”. It will be understood that terms, such as those defined in generally used dictionaries, should be interpreted as having a meaning that is consistent with meanings understood in the context of the related art, and will not be interpreted in an idealized or overly formal sense unless expressly so defined herein.

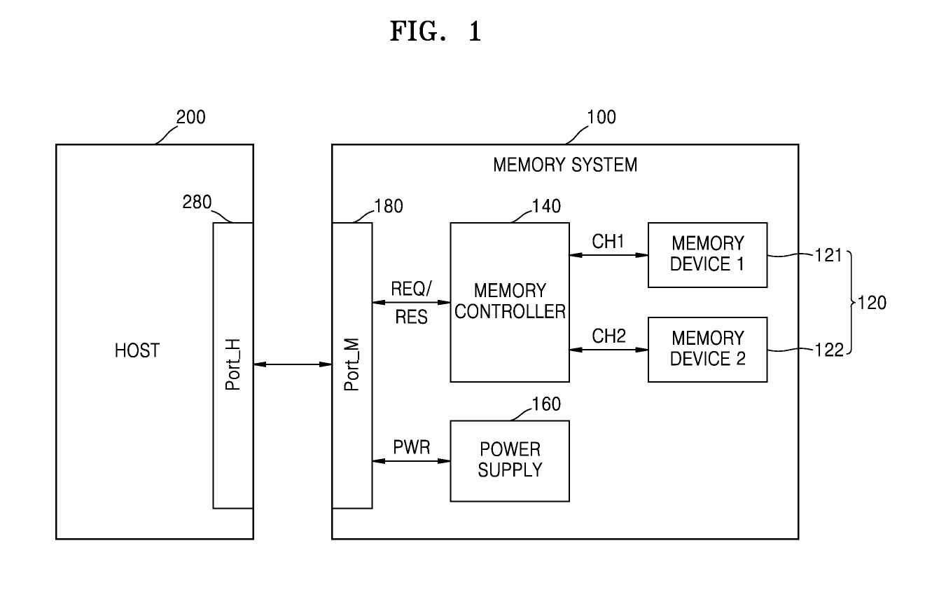

Examples of memory systems according to the inventive concept will now be generally described with reference to the block diagram of FIG. 1. Referring to FIG. 1 a memory system 100 according to the inventive concept may include at least one memory device 120, a memory controller 140, a power supply 160, and a port 180 by which the memory system 100 and a host 200 may communicate with each other.

Each memory device 120 may include a memory cell array including a plurality of memory cells. According to an example of the inventive concept, the memory cell array may be a 3-dimensional (3D) memory array. The 3D memory array may be monolithically formed in one or more physical levels of a planar array of memory cells having an active area disposed above a silicon substrate and circuitry associated with the operation of those memory cells, whether such associated circuitry is above or within such substrate. The term “monolithic” refers to a characteristic in which each planar array (level( )of the memory cells is directly disposed on an underlying planar array (level) of the memory cells.

The following patent documents, which are hereby incorporated by reference, disclose monolithic three-dimensional memory arrays in which word lines and/or bit lines are shared by the memory cells of the various levels: U.S. Pat. Nos. 7,679,133; 8,553,466; 8,654,587; 8,559,235; and US Pat. Pub. No. 2011/0233648.

According to an example of the inventive concept, the 3D memory array includes vertical NAND strings that are vertically oriented such that at least one memory cell is located over another memory cell. The at least one memory cell may comprise a charge trap layer. That is, the plurality of memory cells may be 3D vertical NAND (VNAND) flash memory cells. Hereinafter, the inventive concept will be described by way of an example in which the plurality of memory cells of the memory cell array of the memory device 120 are flash memory cells. In another example, the memory cells of the memory device 120 may consist of a 2-dimensional (i.e., a planar array of) NAND flash memory cells. However, the inventive concept is not limited to the examples described above. In a further example, the plurality of memory cells are resistive memory cells such as a resistive RAM (RRAM), a phase change RAM (PRAM), or a magnetic RAM (MRAM).

In one example, each memory cell of the memory cell array may store 2 bits of data or more. In one example, each memory cell is a multi level cell (MLC) storing 2 bits of data. In another example, each memory cell of the memory cell is a triple level cell (TLC) storing 3 bits of data. However, the inventive concept is not limited to these examples. That is, each memory cell of the memory cell array may store 4 or more bits of data, or may be a single level cell (SLC) storing 1 bit.

The at least one memory device 120 may be connected to the memory controller through one or more channels. In the example illustrated in FIG. 1, a first memory device 121 is connected to the memory controller 140 through a first channel CH1, and a second memory device 122 is connected to the memory controller 140 through a second channel CH2. Although the two memory devices 121, 122 and the two channels CH1, CH2 are shown, according to an example of the inventive concept, the memory system 100 may include only one memory device and one channel, or may include three or more memory devices and three or more channels.

The memory controller 140 may receive a request REQ from the host 200 through the port 180, and may transmit a response RES to the host 200 through the port 180. For example, the memory controller 140 may receive a read request of data from the host 200 through the port 180, and in response to the request, may read the data stored in the memory device 120 and transmit the data to the host 200 through the port 180.

The power supply 160 may receive power PWR from the host 200 through the port 180, and may supply power to components of the memory system 100, for example, to the memory device 120 and the memory controller 140, based on the received power PWR.

The port 180 may include a plurality of pins, and the number, sizes, and arrangement of the pins may be determined based on an interface protocol for communicating with the host 200. For example, the memory system 100 and the host 200 may communicate with each other through at least one of various interface protocols such as USB, MMC, PCI-E, advanced technology attachment (ATA), Serial-ATA, Parallel-ATA, SCSI, ESDI, integrated drive electronics (IDE), and the like.

According to an example of the inventive concept, the memory system 100 supports various form factors of substantially identically configured systems, each form factor being a different group of standard physical characteristics of the system 100. Hence, each form factor is representative of a respective “form” of the memory system. More specifically, the memory system 100 includes a wiring board, such as a printed circuit board (PCB), and the components of the memory system 100, e.g., the at least one memory device 120, the memory controller 140, and the power supply 160 attached to the wiring board. The wiring board allows for the one or memory devices 120, the memory controller 140, and the power supply 160 of different sizes (physical dimensions) to be attached thereto and operatively connected to one another, as will be described in more detail later on. By supporting the plurality of form factors the memory system 100 can be used to realize higher production efficiency in the manufacturing of electronic systems than a memory system of one particular form factor only.

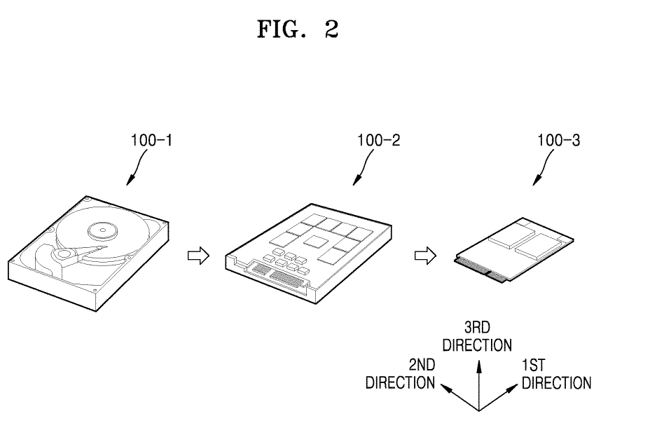

FIG. 2 shows some specific examples of memory systems for use in explaining a memory system that may benefit from the above-described advantage according to the inventive concept. As the electronics industry has evolved, memory systems including semiconductor memory devices have taken the place of general means for data storage, such as magnetic disks, magnetic tapes, optical disks, and the like. Memory systems including semiconductor memory devices consume less power, are smaller (more miniaturized), and have higher storage capacities than their prior art counterparts of the types enumerated above.

FIG. 2 shows one of these prior art counterparts, namely, a hard disk drive (HDD) 100-1 which includes a platter in which data is stored in a magnetic coating on a surface of the platter. The platter may be rotated by a spindle motor, and data may be written on or read from the platter by an input/output head. A hard disk drive 100-1 is relatively large due to the motor for rotating the platter, the input/output head for writing data on the platter, and the like. Examples of the form factors that hard disk drive (HDD) 100-1 may take include 8 inch, 5.25 inch, 3.5 inch, 2.5 inch, 1.8 inch, or 1 inch.

FIG. 2 also shows an example of a conventional solid state drive (SSD) 100-2 as an example of a memory system that has replaced hard disk drives (HDD) in many applications. Solid state drive (SSD) 100-2 may include a flash memory such as a non-volatile memory device, and may store data in memory cells of the flash memory. The solid state drive 100-2 may comply with any of the form factors that the hard disk drive 100-1 may have for compatibility with products that would otherwise employ the hard disk drive 100-1, and may support the same interface protocol as the hard disk drive 100-1.

However, there is an ever increasing demand for electronic products that require a memory system having the basic configuration shown in FIG. 1 and which are smaller and operate at higher speeds than existing devices such as the conventional solid state drive 100-2 shown in FIG. 2. That is, a memory system 100 that is more compact and supports a higher-speed interface protocol than existing systems, such as HDDs and SSDs of the types 100-1 and 100-2 are in demand. To meet such a demand, memory devices having form factors of relatively small sizes, for example, a mSATA standard expressing a PCI Express Mini Card layout, an M.2 standard, and the like have been proposed. A compact solid state drive 100-3 as shown in FIG. 2 can be fabricated to such industry standards. The compact solid state drive 100-3 may include at least one package attached to a wiring board, for example, a printed circuit board (PCB). The form factors for a compact SSD may include its thickness (that is, its physical dimension in the 3^{RD} direction in FIG. 2), its length and its width (that is, its horizontal dimensions in the 1^{ST} and 2^{ND} orthogonal directions in FIG. 2). Hereinafter, examples of memory system 100 of FIG. 1 according to the inventive concept and including a wiring board and at least one package attached to the wiring board, as in the solid state drive 100-3 shown in FIG. 2, will be described in more detail.

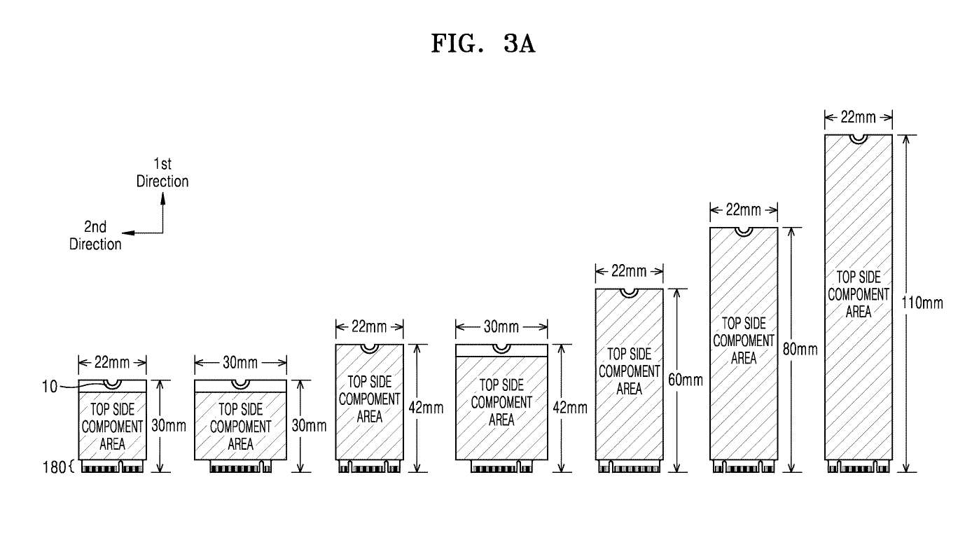

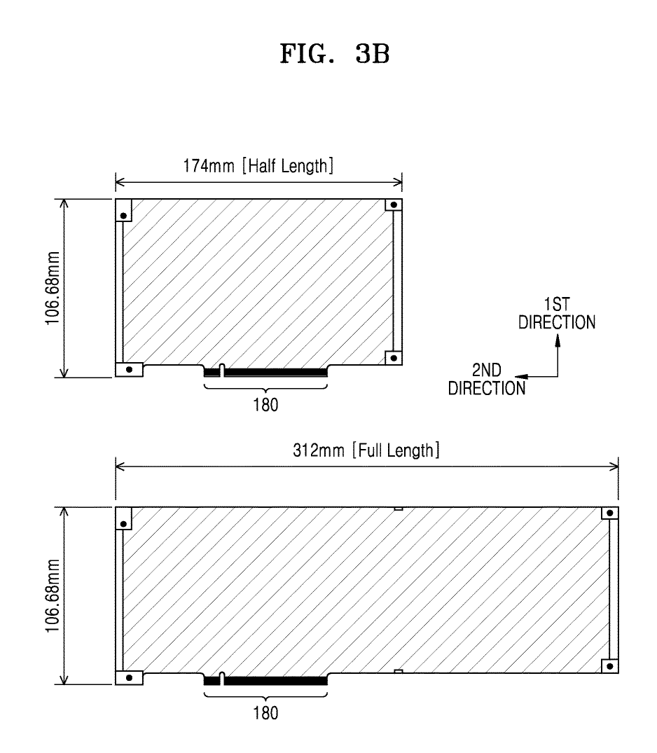

FIGS. 3A and 3B each show a set of examples of memory systems 100 of FIG. 1 but in which the memory systems of each set have different form factors. Specifically, FIG. 3A shows memory systems of different form factors but which each meet the M.2 industry standard, and FIG. 3B shows PCI cards of different form factors.

The form factors of memory systems conforming to an industry standard known as M.2 include standards for the thickness and the horizontal dimensions (a length and width) of the memory systems. Referring to FIG. 3A, M.2 requires the horizontal dimension of the memory system 100 in one direction (the dimension in the 2^{ND} direction in the figure) to be 22 mm or 30 mm, and allows for the horizontal dimension in the other direction (the dimension in the 1^{ST} direction in the figure) to be 30 mm, 42 mm, 60 mm, 80 mm, or 110 mm.

Referring to FIG. 3A, the form factors also include standardizations for the port 180. The port 180 is located at one side of the wiring board, and includes a plurality of contacts for communicating with a host (i.e., the host 200 in FIG. 1). Each of the plurality of the contacts is an exposed pattern of conductive material, e.g., a pattern of metal such as copper. The exposed patterns are inserted in and connected to corresponding contacts of a socket of the host 200.

In addition, M.2 also defines a standardized structure for mounting the memory system 100 in the host 200 and fixing the memory system 100 to the host 200. Referring to FIG. 3A, each of the form factors under the M.2 standard dictates that a structure defining a semicircular recess be provided in a side of the device opposite the side including the port 180. An exposed (semicircular) conductive pattern extends along a rim of the structure, and may be electrically connected to a conductor of the host 200 when the memory system 100 is mounted to, i.e., inserted in, the host 200. The conductive pattern on the rim of the structure corresponds to a ground node of the memory system 100, and may be connected to the conductor corresponding to a ground node of the host 200 when the memory system 100 is mounted to the host 200.

Referring to FIG. 3B, the form factors of PCI cards include a second horizontal dimension of the card (dimension in the 2^{ND} direction) of 174 mm or 312 mm, and a first horizontal dimension of the card (dimension in the 1^{ST} direction) of 106.68 mm. The second dimension of the PCI card defines the maximum length of the memory system 100 and a second dimension of 174 mm (or less) may be referred to as a half length, while a second dimension of 312 mm may be referred to as a full length. As is also shown in FIG. 3B, the port 180, according to both form factors of PCI cards, has the same position and shape regardless of whether the second dimension is the half length or the full length.

Although memory systems 100 according to the inventive concept have been described hereinabove as complying with the M.2 industry standard or as being in the form of PCI cards, it will be understood that the inventive concept is not limited thereto. Rather, the inventive concept can be applied to other types of memory systems that maybe configured substantially identically to one another but which have different form factors in the art.

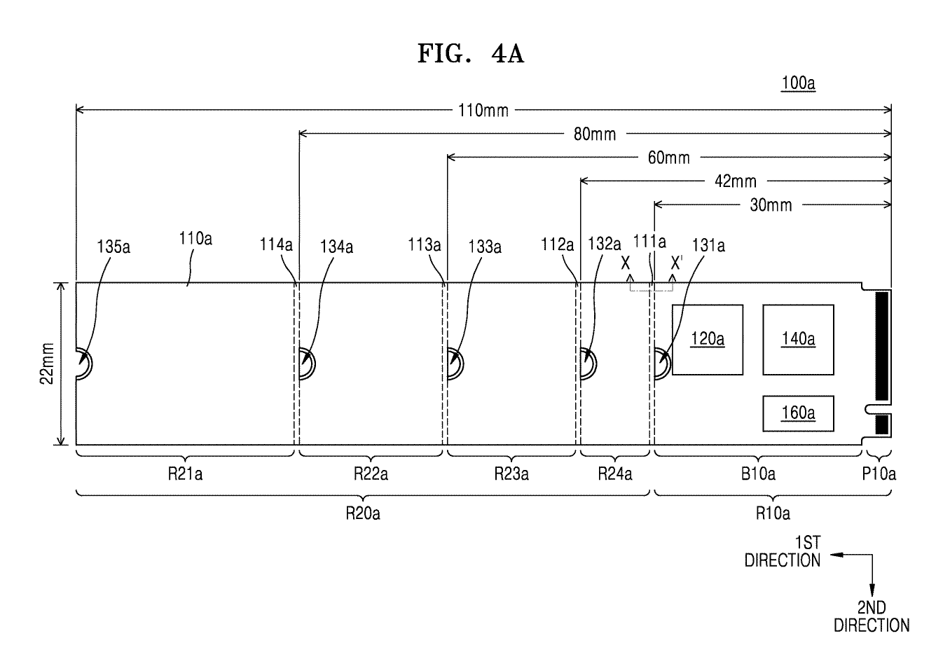

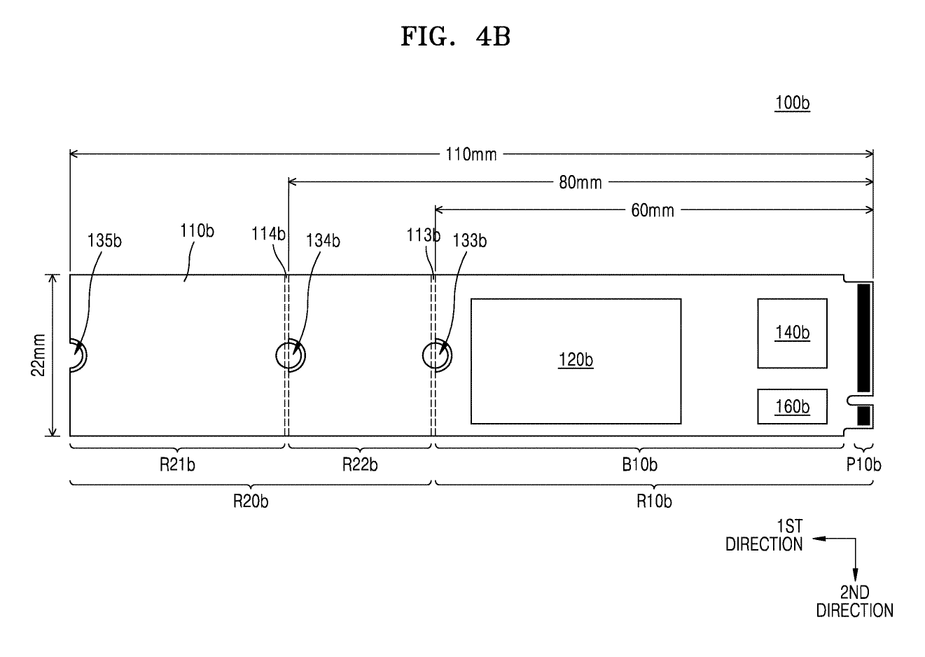

FIGS. 4A and 4B are plan views of examples of memory systems 100 of FIG. 1 according to the inventive concept. Specifically, FIGS. 4A and 4B show examples 100a, 100b of memory systems 100 each conforming to the M.2 standard.

In the example shown in FIG. 4A, the memory system 100a includes a wiring board 110a, and a memory device 120a, a memory controller 140a, and a power supply 160a, which are attached to one surface of the board 110a. The memory device 120a, the memory controller 140a, and the power supply 160a may be embodied as packages attached to the board 110a. Each respective package may include a plurality of exposed conductors such as pins, and the exposed conductors may be disposed on and connected to a conductive pattern on a surface of a substrate of the wiring board 110a. Although the memory device 120a, the memory controller 140a, and the power supply 160a may be embodied as separate packages in the example shown in FIG. 4A, in other examples of the inventive concept, at least two of the memory device 120, the memory controller 140, and the power supply 160 may be part of the same package. According to an example of the inventive concept, the memory system 100a includes a first region R10a and a second region R20a.

The first region R10a may include a port region P10a and a body region B10a. The port region P10a may include a port, e.g., the port 180 of FIG. 1, which includes a plurality of external contacts to be electrically connected to the host 200 in order for the memory system and the host 200 to communicate with each other. The body region B10a may include a conductive pattern to which the memory device 120a, the memory controller 140a, and the power supply 160a are attached and electrically connect to the wiring board. As described above with reference to FIG. 1, the memory controller 140a may control the memory device 120a in response to a signal received from the host 200 through the port disposed in the port region P10a. In addition, the power supply 160a may supply power to the memory device 120a and the memory controller 140a based on power received from the host 200 through the port disposed in the port region P10a.

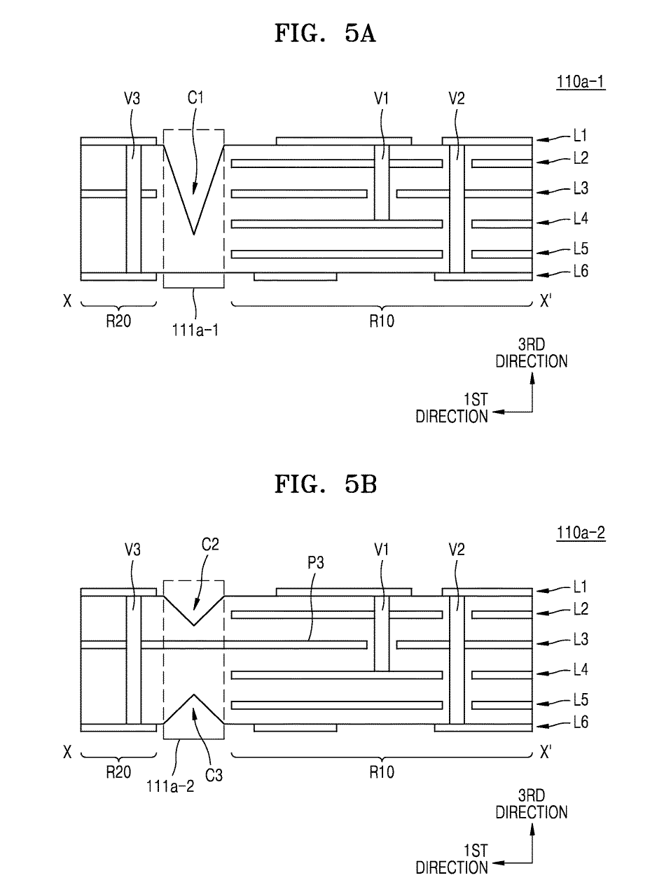

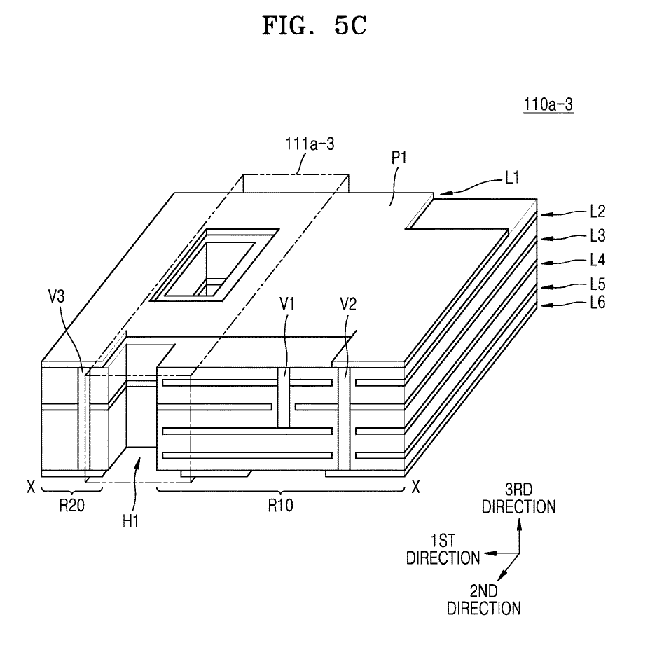

The second region R20a may adjoin the first region R10a, and may be separable from the first region R10a. Referring still to FIG. 4A, a boundary region 111a directly interposed between the first region R10a and the second region R20a (referred to hereinafter simply as the boundary 111a) facilitates a separating of the wiring board 110a into the first region R10a and the second region R20a. For example, as described below with reference to FIGS. 5A to 5C, the boundary 111a between the first region R10a and the second region R20a may be frangible. For example, the wiring board 110a may be thinner at the boundary 111a than at regions directly on opposite sides of the boundary 111a and/or may include one or more through-holes at the boundary 111a. Thus, the memory system 100a can be separated into two sections including the first region R10a and the second region R20a, respectively.

According to an example of the inventive concept, the first region R10a may correspond to a first form factor of the memory system 100a, and a region including the first and second regions R10a, R20a may correspond to a second form factor of the memory system 100a. That is, as shown in FIG. 4A, the first region R10a may correspond to a form factor including a first horizontal dimension of 30 mm and a second horizontal dimension of 22 mm, that is, a form factor of 30 mm×22 mm, and the region including the first and second regions R10a, R20a may correspond to a form factor including a first horizontal dimension of 110 mm and a second horizontal dimension of 22 mm, that is, a form factor of 110 mm×22 mm. Since the memory system 100a supports the different form factors, the memory system 100a may be adapted for use in any of several different applications. For example, a user of the memory system 100a may use the memory system 100a as is in a first apparatus supporting a memory system having a form factor of 110 mm×22 mm, and may separate the second region R20a from the first region R10a, discard the second region 20a and use the resulting memory system 100a in a second apparatus supporting a memory system having a form factor of 30 mm×22 mm. In addition, by producing the memory systems 100a a manufacturer of memory systems may avoid the need to separately manufacture memory systems having the form factors of 110 mm×22 mm and 30 mm×22 mm, i.e., the inventive concept allows for the production efficiency of memory systems to be increased.

According to an example of the inventive concept, the second region R20a may include a plurality of sub-regions R21a to R24a, and the plurality of sub-regions R21a to R24a may be separable from each other. Referring to FIG. 4A, the first sub-region R21a can be separated from the second sub-region R22a at a boundary 114a, the second sub-region R22a can be separated from the third sub-region R23a at a boundary 113a, and the third sub-region R23a can be separated from the fourth sub-region R24a at a boundary 112a. Like at the boundary 111a between the first and second regions R10a, R20a, the wiring board 110 may be thinnest and may include a plurality of holes at the boundaries 111a to 113a between the sub-regions R21a to R24a.

According to an example of the inventive concept, a region including the first region R10a and at least one of the sub-regions R21a to R24a may correspond to a third form factor of the memory system 100a. Referring to FIG. 4A, a region including the first region R10a and the fourth sub-region R24a may correspond to a form factor of 42 mm×22 mm, and a region including the first region R10a, the third sub-region R23a, and the fourth sub-region R24a may correspond to a form factor of 60 mm×22 mm. In addition, a region including the first region R10a and the second to fourth sub-regions R22a to R24a may correspond to a form factor of 80 mm×22 mm, and a region including the first region R10a and the first to fourth sub-regions R21a to R24a may correspond to a form factor of 110 mm×22 mm. Thus, the memory system 100a may support three or more different form factors.

As shown in FIG. 4A, the wiring board 110a may include holes 131a, 133a and 134a. The holes 131a, 133a and 134a each correspond to a recess of a contact structure of the form factors supported by the memory system 100a, respectively. As described above with reference to FIG. 3A, a conductive pattern may be exposed along a rim of each of the contact structures and thus be disposed alongside the holes 131a, 133a and 134a and recess 135a, and the exposed conductive pattern may correspond to a ground node of the memory system 100a.

Referring to FIG. 4B, a memory system 100b according to the inventive concept may also include a wiring board 110b, and a memory device 120b, a memory controller 140b, and a power supply 160b attached to one side of the board 110b. The memory device 120b, the memory controller 140b, and the power supply 160b may be realized in the form of two or more discrete packages as described with reference to the memory device 120, the memory controller 140, and the power supply 160 of FIG. 1, respectively.

According to an example of the inventive concept, the memory system 100b may support only some of the plurality of form factors defined by the M.2 standard. In this case, for example, the memory system 100b of FIG. 4B may provide a higher capacity than the memory system 100a of FIG. 4A. That is, the memory device 120b of memory system 100b may have a higher storage capacity than the memory device 120a of the memory system 100a. Thus, the memory device 120b may be provided in a package larger than that comprising the memory device 120a and may include a greater number of memory cell arrays than the memory device 120a. Therefore, a first region R10b of the memory system 100b, to which the memory device 120b is attached, may be larger than the first region R10a of the memory system 100a. In these examples, while the memory system 100a may support five form factors including a form factor of the smallest dimensions within the M.2 standard, the memory system 100b of FIG. 4B may support only three of the form factors.

Referring to FIG. 4B, the first region R10b may include a port region P10b and a body region B10b. A second region R20b may adjoin the first region R10b, and may be separable from the first region R10b. The second region R20b may include first and second sub-regions R21b, R22b, and the first and second sub-regions R21b, R22b may be separable from each other. At a boundary 113b between the first and second regions R10b, R20b and a boundary 114b between the first and second sub-regions R21b, R22b, the wiring board 110b may be thinner thickness than at other regions and/or may include one or more through-holes.

The wiring board 110b of FIG. 4B may also include holes 134b, 133b. The holes 134b, 133b in FIG. 4B may be circular and along with recess 135b may each be used to provide the recessed contact structures of the form factors of all memory systems conforming to the M.2 standard.

FIGS. 5A to 5C show examples of wiring boards according to the inventive concept. Specifically, FIGS. 5A to 5C show exemplary structures of boundary regions of wiring boards between any two regions of the wiring board 110a of FIG. 4A according to the inventive concept.

Each of the examples of the wiring board 110a shown in FIGS. 5A to 5C is a printed circuit board (PCB) having six layers L1 to L6 of conductive patterns separated by layers of insulating material which in this case may constitute a rigid substrate. In addition, each of the examples of the wiring board 110a shown in FIGS. 5A to 5C includes vias V1, V2 each electrically connecting at least two different layers of conductive patterns to each other. The conductive pattern of the third layer L3 in the examples shown FIGS. 5A to 5C correspond to the ground node of the memory system 100a (and thus includes the semi-circular conductive patterns forming the external contacts shown in FIG. 4A). That is, the pattern of the third layer L3 may have a ground potential when the memory system 100a is operated. The pattern of in the third layer L3 may thus spread throughout the wiring board 110a while being insulated from those vias to be provided with operating voltages, i.e., potentials different from that of the ground node.

Referring to FIG. 5A, a wiring board 110a-1 may include a first region R10 and a second region R20, and may include a V-cut C1 at a boundary 111a-1 between the first and second regions R10, R20. The V-cut C may refer to recess having a ‘V’-shaped vertical profile. As shown in FIG. 5A, the V-cut C1 may be extend vertically (in the 3^{RD} direction) from one major surface of the substrate of the wiring board 110a-1 making the wiring board 110a-1 frangible at the boundary 111a-1. Thus, the second region R20 can be readily separated from the first region R10.

Referring to FIG. 5B, a wiring board 110a-2 may include two V-cuts C2, C3 at a boundary 111a-2 between the first and second regions R10, R20. As shown in FIG. 5B, the V-cuts C2, C3 may extend from both major surfaces of the substrate of the wiring board 110a-2 in the 3^{RD} direction, that is, from upper and lower surfaces of the substrate of the wiring board 110a-2, respectively. Thus, the second region R20 can be readily separated from the first region R10.

In the examples of FIGS. 5A and 5B, the wiring boards 110a-1, 110a-2 of FIGS. 5A and 5B are thinnest at the boundaries 111a-1, 111a-2 between the first and second regions R10, R20.

Referring to FIG. 5C, wiring board 110a-3 include first and second regions R10, R20, and has a plurality of through-holes H1 at a boundary 111a-3 between the first and second regions R10, R20. The plurality of through-holes H1 makes the wiring board 110a-3 frangible at the boundary 111a-3, such that the second region R20 may be readily separated from the first region R10. Although the through-holes H1 having a quadrangular cross section as shown in FIG. 5C, the holes may have other cross-section shapes. For example, the through-holes at the boundary 111a-3 may have circular cross sections.

According to an example of the inventive concept, the second region R20 may include a pattern corresponding to a ground node. That is, the second region R20 may include the pattern electrically connected to a pattern corresponding to a ground node of the first region R10. For example, as shown in FIG. 5B, a pattern P3 in the third layer L3 may extend in a first direction across the boundary 111a-2, and the second region R20 may be electrically connected to the pattern P3 through a via V3 and may include patterns in first and sixth layers L1, L6, respectively. In addition, as shown in FIG. 5C, a pattern P1 in the first layer may extend in the first direction across the boundary 111a-3, and the second region R20 may include the patterns in the third and sixth layers L3, L6 and electrically connected to the pattern P1 through a via V3.

The pattern in the second region R20 and corresponding to the ground node may have an exposed portion, and may be connected to the conductor corresponding to the ground node of the host 200 through the exposed portion when the memory system 100a is mounted in the host 200. For example, as described above with reference to FIG. 3A, the pattern of the second region corresponding to the ground node may be electrically connected to the exposed pattern on the semicircular rim of the recessed structure. The pattern corresponding to the ground node in the second region R20 delivers the ground potential from the host 200 to the memory system 100a, and transfers heat generated by the memory system 100a to the host 200 system as well, thereby serving as a heat dissipater of the memory system 100a. As such, the pattern corresponding to the ground node in the second region R20 may be referred to as a heat dissipation pattern, and the heat dissipation pattern may extend throughout the second region R20.

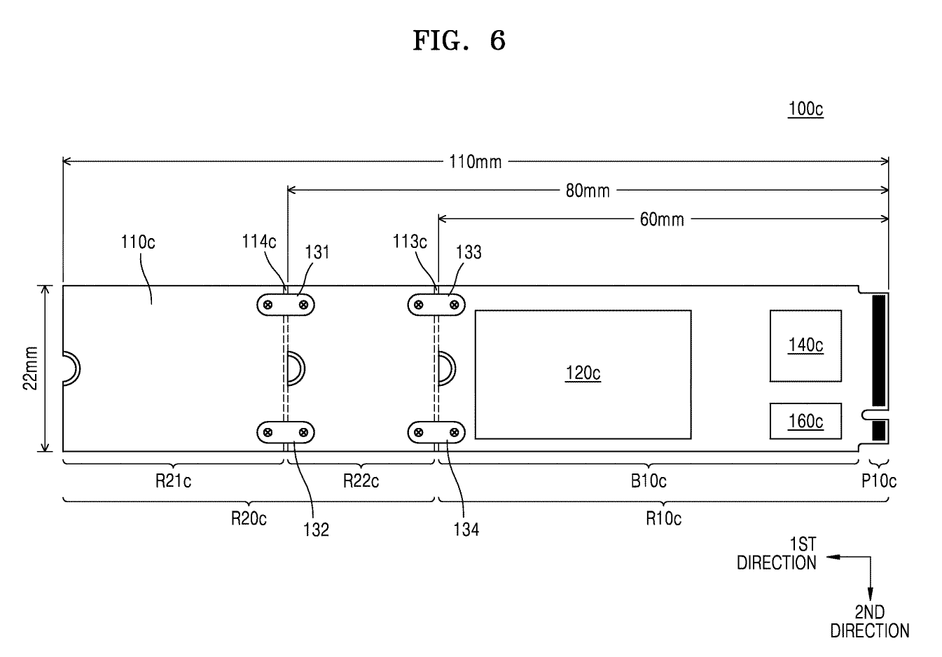

FIG. 6 shows still another example of a memory system according to the inventive concept. Referring to FIG. 6, the memory system 100c of this example has first and second regions R10c, R20c, and includes a wiring board and a memory device 120c, a memory controller 140c, and a power supply 160c attached to the wiring board and confined to the first region R10c.

According to an example of the inventive concept, the memory system 100c may include at least one coupling used for detaching (uncoupling) and reattaching (re-coupling) respective regions of the memory system. For example, as shown in FIG. 6, the memory system 100c may include four couplings 131 to 134. The two couplings 131, 132 may be used for re-coupling first and second sub-regions R21c, R22c, and the two couplings 133, 134 may be used for re-coupling the first and second regions R10c, R20c (or the first region R10c and the second sub-region R22c). The regions re-coupled by the couplings 131 to 134 may be separated again by decoupling the couplings 131 to 134 from at least one of the regions. For example, the first and second sub-regions R21c, R22c re-coupled by the two couplings 131, 132 may be separated again by decoupling the two couplings 131, 132 from the first and second sub-regions R21c, R22c.

Wiring board 110c includes structure or means by which the couplings 131 to 134 can be attached (coupled) and detached (uncoupled) from the substrate of the wiring board. For example, the first region R10c may include a plurality of threaded holes by which the couplings 133, 134 are screwed to the substrate. In addition, the memory system with the couplings 131 to 134 in place may have a thickness satisfying that of a form factor, that is, may have a standard dimension in the 3^{RD} direction perpendicular to 1^{ST} and 2^{ND} horizontal directions. As described above, a standard such as the M.2 standard may define a thickness of the memory system 100c, and the couplings 131 to 134 may have a height allowing the memory system 100c, in which the couplings 131 to 134 are coupled, to have a thickness defined by the M.2 standard.

Furthermore, the couplings 131 to 134 may be formed of electrically conductive material such as a metal, and may electrically connect conductive patterns of two regions of the memory system, e.g., patterns corresponding to the ground nodes.

Although an example in which two couplings are used to detachably connect two different regions is shown in FIG. 6, according to the inventive concept, one coupling, or three or more couplings may be used to detachably connect two different regions.

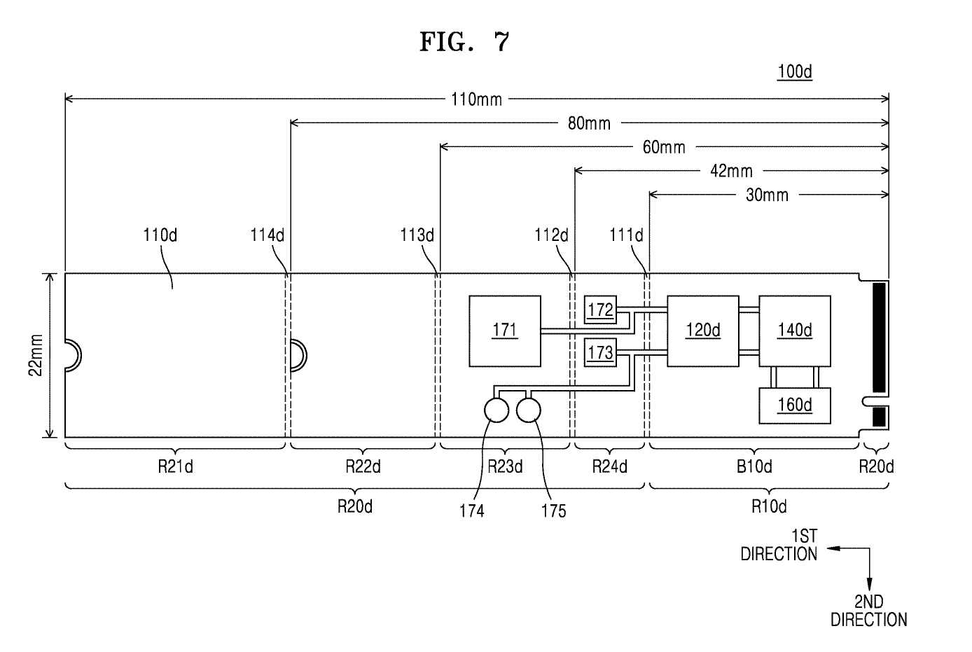

FIG. 7 shows another example of a memory system according to the inventive concept. Referring to FIG. 7, memory system 100d may include first and second regions R10d, R20d, and the second region R20d may include a plurality of sub-regions R21d to R24d. In addition, the memory system 100d may include a memory device 120d, a memory controller 140d, and a power supply 160d, which are attached to the first region R10d.

The memory system 100d of this example includes at least one circuit for sudden power off recovery (SPOR, referred to as SPOR hereinafter), which is confine to the second region R20d. SPOR may refer to a function allowing operations performed in the memory system 100d to be normally terminated and preventing occurrence of errors in the memory system 100d by supplying power to the memory system 100d for a certain period of time if power supplied to the memory system 100d is suddenly shut off. The SPOR circuit may include a capacitor having a high capacitance, and a battery. The SPOR circuit may occupy a larger area, i.e., may have a larger footprint, than circuits performing other functions, respectively, in the memory system.

Referring to FIG. 7, all elements 171 to 175 of the SPOR circuit are disposed in the second region R20d of the memory system 100d. The provision of the SPOR circuit allows the memory system 100d to be stably operated.

When the memory system 100d is used in a server system, stable operation of the memory system 100d may be more important than the size of the memory system 100d. On the other hand, when the memory system 100d is used in a portable electronic apparatus such as a tablet PC, the size of the memory system 100d may be important. Thus, the memory system 100d according to the inventive concept can satisfy all conditions required by the two applications.

The elements 171 to 175 of the SPOR circuit do not affect normal operation of the memory device 120d, the memory controller 140d, and the power supply 160d, which are confine to the first region R10d. That is, the memory circuitry can operate independently of the SPOR circuit. Thus, even though the SPOR circuit is removed by separating the second region R20d from the first region R10d, the resulting memory system 100d is operable.

In the example shown in FIG. 7, although the elements 171 to 175 of the SPOR circuit are shown as being disposed in the third and fourth sub-regions R23d, R24d, additional elements of the SPOR circuit may be provided in the first and second sub-regions R21d, R24d.

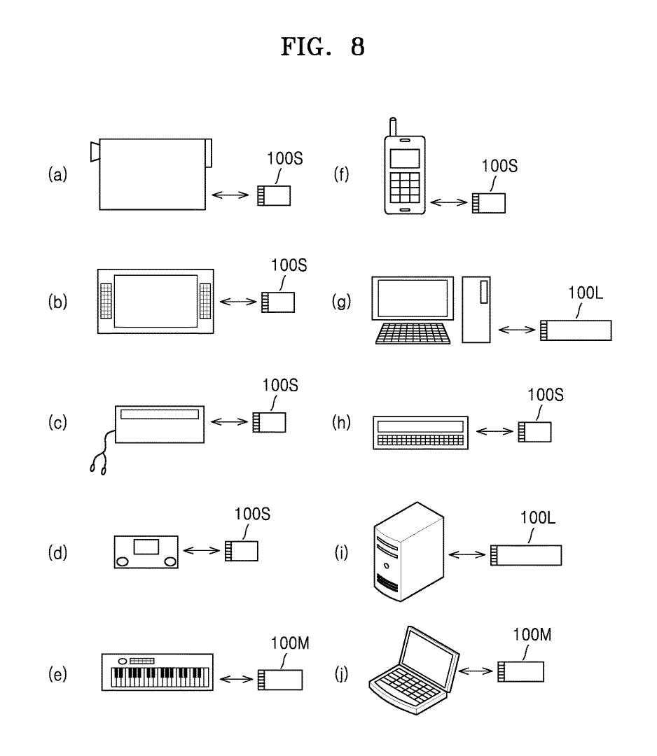

FIG. 8 shows examples of the memory system 100 of FIG. 1 in various applications according to the inventive concept. Referring to FIG. 8, the memory system 100 may be used for (a) video cameras, (b) televisions, (c) audio devices, (d) game devices, (e) electro-acoustic devices, (f) mobile phones, (g) desktop computers, (h) personal digital assistants (PDAs), (i) server systems, (j) laptop computers, and the like.

In the examples of FIG. 8, memory system 100S may conform to a form factor of a relatively small size, memory system 100L may conform to a form factor of a relatively large size, and memory system 100M may conform to a form factor of a medium size between the size of the memory system 100S and the size of the memory system 100L. For example, the memory system 100S may be configured by separating the second region from the first region, the memory system 100M may be configured by separating the system at least one sub-region of the second region, and the memory system 100L may include the first and second regions.

As shown in FIG. 8, the memory system 100S conforming to the form factor of the relatively small size may be used for the (a) video cameras, the (b) televisions, the (c) audio devices, the (d) game devices, the (f) mobile phones, the (h) PDAs, and the like, which are handheld apparatuses. In addition, the memory system 100M conforming to the form factor of the medium size may be used for the (e) electro-acoustic devices, the (j) laptop computers, and the like, which are portable apparatuses having a relatively large footprint. Furthermore, the memory system 100L conforming to the form factor of the relatively large size may be used for the (g) desktop computers, the (i) server systems, and the like, which require high performance and capacity.

As described above, the memory systems 100S, 100M, 100L corresponding to individual memory systems of different form factors may each be derived from one (the same) memory system according to the inventive concept. That is, the memory systems 100S, 100M, 100L all include the same first region of a memory system according to the inventive concept where the major components necessary for an independent operation of the system are provided, at least the systems 100S, 100M may be realized by separating (e.g., uncoupling) regions of the system from one another. In some examples, the system 100L may be reconstituted by re-coupling regions of the system. There may be a tool facilitating the uncoupling/re-coupling of respective regions such that a user of the memory system 100 can use the memory system 100 for various applications, and the tool may be provided by a producer of the memory system 100 in conjunction with the memory system 100.

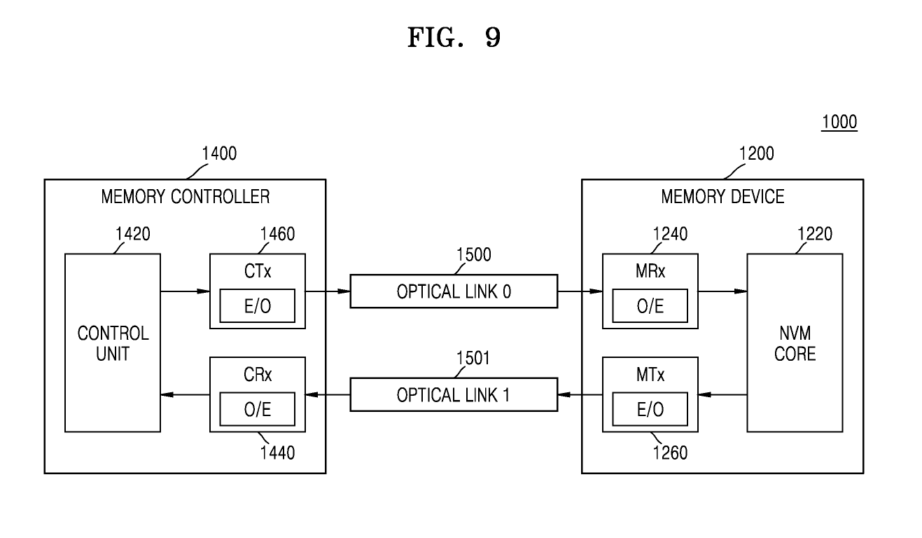

FIG. 9 shows a memory system 1000, which includes optical links, according to an example of the inventive concept. Referring to FIG. 9, the memory system 1000 may include a memory device 1200 and a memory controller 1400. In this example, the memory device 1200 will be described as a non-volatile memory device including a non-volatile memory cell.

The memory device 1200 may include a non-volatile core 1220, which includes a memory cell array including a non-volatile memory cell, an optical receiver 1240, which includes an optical-to-electrical (O/E) conversion device converting an optical signal into an electrical signal, and an optical transmitter 1260, which includes an electrical-to-optical (E/O) conversion device converting an electrical signal into an optical signal.

The memory controller 1400 may include a control unit 1420, an optical receiver 1440, which includes an optical-to-electrical (O/E) conversion device converting an optical signal into an electrical signal, and an optical transmitter 1460, which includes an electrical-to-optical (E/O) conversion device converting an electrical signal into an optical signal.

Optical links 1500, 1501 for transmitting and receiving data may be provided between the memory device 1200 and the memory controller 1400. Referring to FIG. 4A, the optical links 1500, 1501 may be formed in the first region R10a in the wiring board 110a. According to another example, the memory device 1200 and the memory controller 1400 may transmit and receive data through one optical link.

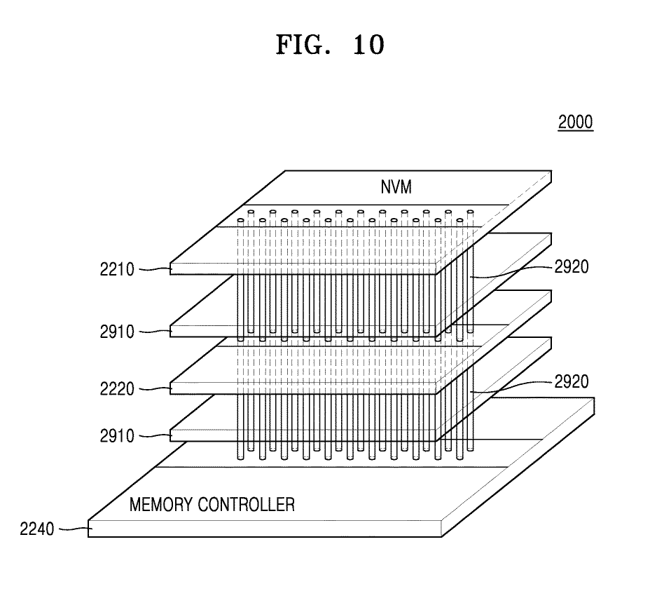

FIG. 10 shows an example of a structure in which the memory device 120 and the memory controller 140 of FIG. 1 are included in one package 2000 according to the inventive concept. In this example, the memory device 120 will be described as a non-volatile memory device including a non-volatile memory cell.

Referring to FIG. 10, an interface chip 2240 including the memory controller may be located in the lowest layer, at least one memory chip 2210, 2220 including a non-volatile memory cell (or a non-volatile memory cell array) may be located on the interface chip 2240, and magnetic field protective layers 2910 may be located between the interface chip 2240 and the memory chip 2210, 2220. The magnetic field protective layers 2910 may block a magnetic field generated between chips operated based on power supplied to the package 2000, that is, between the interface chip 2240 and the memory chips 2210, 2220.

Since the interface chip 2240 and the memory chips 2210, 2220 may be electrically connected through a plurality of through silicon vias (TSVs), the memory controller of the interface chip 2240 may control the memory devices of the memory chips 2210, 2220, and may transmit data to and receive data from the memory devices. The interface chip 2240 may be electrically connected to a plurality of pins exposed to the outside of the package 2000.

Referring to FIG. 4A together with FIG. 10, the package 2000 may be attached to the first region R10a of the wiring board 110a. The one package includes the memory device and the memory controller, thereby reducing the patterns formed on the wiring board 110a. That is, since a plurality of wires connecting the memory device to the memory controller may be realized as the TSVs and be included in the package 2000, the patterns of the wiring board 110a, which are required if the memory device and the memory controller are realized as individual packages, are rendered unnecessary.

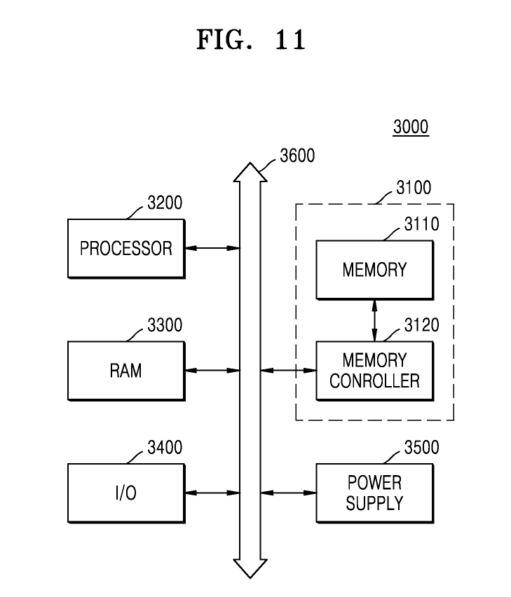

FIG. 11 is a block diagram of examples of a computing system 3000 including a memory system 3100 according to the inventive concept. Referring to FIG. 11, the computing system 3000 may include the memory system 3100, a processor 3200, a RAM 3300, an input/output device 3400, and a power supply 3500. The computing system 3000 may further include ports allowing communication with a video card, a sound card, a memory card, a USB device, and the like, or communication with other electronic apparatuses, although the ports are not shown in FIG. 11. The computing system 3000 may be realized as a personal computer, or be realized as a portable electronic apparatus such as a notebook computer, a mobile phone, a personal digital assistant (PDA), a camera, and the like.

The processor 3200 may perform specific calculations or tasks. According to an example, the processor 3200 may be a micro-processor or a central processing unit (CPU). The processor 3200 may communicate with the RAM 3300, the input/output device 3400, and the memory system 3100 through a bus 3600 such as an address bus, a control bus, a data bus, and the like. The processor 3200 may also be connected to an extension bus such as a peripheral component interconnect (PCI) bus.

The memory system 3100 may be realized according to the inventive concept, and may be configured to have a form factor required by the computing system 3000.

The RAM 3300 may store data required for operation of the computing system 3000. For example, the RAM 3300 may be realized as a DRAM, a mobile DRAM, an SRAM, a PRAM, an FRAM, an RRAM, and/or an MRAM.

The input/output device 3400 may include an input means, such as a keyboard, a keypad, a mouse, or the like, and an output means, such as a printer, a display, or the like. The power supply 3500 may supply an operation voltage required for operation of the computing system 3000.

Although the inventive concept has been particularly shown and described with reference to examples thereof, it will be understood that various changes in form and details may be made to such examples without departing from the spirit and scope of the inventive concept as defined by the following claims.

What is claimed is:

1. A memory system, comprising:
a package comprising a memory device of the memory system; and
a wiring board to which the package is mounted, the wiring board comprising a substrate and at least one layer of a conductive pattern integral with the substrate, and
wherein the memory system has a first region, a second region, and at least one boundary region including a first boundary region between the first region and the second region,
the wiring board is frangible at or physically divided along the first boundary region,
the at least one layer comprises a conductive pattern extending along an outer surface of the substrate in the first region, and the package is confined to the first region as attached to the conductive pattern, and
the first region conforms to a first form factor of the memory system, and a third region consisting of the first and second regions together conform to a second form factor of the memory system.

2. The memory system according to claim 1, further comprising a port in the first region and comprising a plurality of external electrical conductors, and wherein the port conforms to the first and second form factors.

3. The memory system according to claim 2, further comprising a memory controller which controls the memory device, the memory controller being electrically connected to the wiring board and confined to the first region of the memory system.

4. The memory system according to claim 1, wherein the second region comprises a plurality of sub-regions, the at least one boundary region includes a second boundary region between the sub-regions, the wiring board is frangible at or physically divided along the second boundary region, and the first region and one of the sub-regions together conform to a third form factor of the memory system.

5. The memory system according to claim 1, wherein respective dimensions of the first and third regions in a first direction are different from each other and respective widths of the first and third regions in a second direction perpendicular to the first direction are equal to each other.

6. The memory system according to claim 1, wherein the at least one layer comprises a plurality of layers of conductive patterns in the first region, and a heat dissipation pattern in the second region, and the heat dissipation pattern is disposed at the same level as and is connected to one of the conductive patterns in the first region.

7. The memory system according to claim 6, wherein the heat dissipation pattern has a portion that is exposed to the outside of the memory system so as to be directly connectable to a conductor of an external device.

8. The memory system according to claim 7, wherein the heat dissipation pattern constitutes a ground of the memory system.

9. The memory system according to claim 1, further comprising:
at least one component for sudden power off recovery of the memory system,
wherein the at least one layer comprises a conductive pattern in the second region and to which the at least one component is mounted.

10. The memory system according to claim 1, wherein the wiring board is thinner at the first boundary region than at another portion thereof in the first and second regions.

11. The memory system according to claim 10, wherein the wiring board has at least one V-shaped recess extending into the substrate at the first boundary region between the first and second regions.

12. The memory system according to claim 1, wherein the wiring board has a plurality of holes extending through the substrate at the first boundary region between the first and second regions.

13. The memory system according to claim 10, wherein the substrate is physically divided at the boundary region, and further comprising:
at least coupling detachably coupling the first and second regions of the memory system to one another

14. The memory system according to claim 1, wherein the first and second form factors meet the M.2 standard.

15. A wiring board comprising:
a substrate and at least one layer of a conductive pattern integral with the substrate, and
wherein the wiring board has a first region and a second region,
the at least one layer includes a conductive pattern extending along one of oppositely facing major surfaces of the substrate and at which a memory device can be attached and electrically connected to the wiring board,
the wiring board is frangible at or physically divided along the first boundary region, and
wherein the first region conforms to a first form factor of a memory system that employs the memory device, and the first and second regions together conform to a second form factor of the memory system.

16. A memory system, comprising:
a wiring board comprising a substrate and wiring integral with the substrate; and
electronic components of the memory system mounted to the wiring board at the first surface of the substrate and electrically connected to the wiring, and
wherein the memory system has a plurality of body regions integral with one another, a respective boundary region between adjacent ones of each respective pair of the body regions, and means for detaching the adjacent ones of the body regions from one another along the respective boundary region located therebetween,
the electronic components comprise at least one electronic memory and a memory controller operatively electrically connected to the at least one memory,
the first one of the body regions is adjacent to only one other of the body regions such that the first one of the body regions including each said at least one electronic memory and the memory controller can be detached from all other of the body regions along a said boundary region between the first one of the body regions and said one other of the body regions, and
the memory system is operable in at least a first configuration in which the first one and said other of the body regions remain integral with each other, and a second configuration in which the first body region has been detached by virtue of said detaching means from said other of the body regions along the boundary region located therebetween.
whereby the memory system is adaptable for use with any of a plurality of different hosts configured to receive memory systems of different physical dimensions.

17. The memory system according to claim 16, wherein the means for detaching comprises at least one frangible section of the wiring board.

18. The memory system according to claim 17, wherein each said at least one frangible section of the wiring board is a section in which the substrate of the wiring board has at least one recess extending vertically therein each from a respective one of oppositely facing major surfaces of the substrate or has at least one through-hole extending vertically therethrough between the oppositely facing major surfaces.

19. The memory system according to claim 16, wherein the means for detaching comprises at least one coupling by which the adjacent ones of the body regions can be detached from one another and subsequently reattached to one another.

20. The memory system according to claim 16, and having a port region extending along one side of the first one of the body regions at an outer peripheral portion of the memory system, and wherein the memory system further comprises a first set of external conductive contacts confined to the port region, and a respective external conductive contact directly adjacent each said boundary region at level between oppositely facing major surfaces of the substrate of the wiring board and exposed to the outside of the memory system.
